(19) United States
(12) Patent Application Publication
(10) Pub. No.: US 2008/0278186 A1
(43) Pub. Date: Nov. 13, 2008

(54) PIPELINE TEST APPARATUS AND METHOD

(76) Inventor: Jin-kook Jung, Seongnam-si (KR)

Correspondence Address: F. CHAU & ASSOCIATES, LLC, 130 WOODBURY ROAD, WOODBURY, NY, 11797, US

(21) Appl. No.: 12/054,974

(22) Filed: Mar. 25, 2008

(30) Foreign Application Priority Data
May 9, 2007 (KR) 10-2007-0045096

(51) Int. Cl. G01R 31/01

(52) U.S. Cl. 324/755

(57) ABSTRACT

A pipeline test apparatus is provided. The pipeline test apparatus includes a test board. A plurality of stages of sockets are installed on the test board. Each socket is configured to be connected to a device under test (DUT). The sockets of each stage are connected to one of a plurality of different testing devices. Each testing device is configured to perform a unique test on all the DUTs of a corresponding stage.

### CROSS-REFERENCE TO RELATED PATENT APPLICATION

This application claims priority to Korean Patent Application No. 10-2007-0045096, filed on May 9, 2007, in the Korean Intellectual Property Office, the disclosure of which is incorporated by reference in its entirety herein.

### BACKGROUND OF THE INVENTION

1. Technical Field

The present disclosure relates to a method and apparatus for testing a semiconductor, and more particularly, to a method and apparatus for testing a semiconductor by using a pipeline method.

2. Discussion of Related Art

The demand for test equipment which can test semiconductor devices in large quantities has increased with the ever increasing integration and production of semiconductor devices.

However, the number of channels that can be used in test equipment is limited. The number of the channels correspond to the number of signals of a semiconductor device. The number of dies which can be tested at any one time is limited by the number of available channels. Each of the channels can perform various kinds of tests, for example, a function test, a design for testability (DFT) test, an open/short (O/S) test, a leakage current test, an analog test, etc. As illustrated in FIG. 1, all of the tests are performed on a test board 110 by using a single socket 120 coupled with a semiconductor device under test 130 (hereinafter, referred to as a device under test (DUT)).

However, testing costs have increased due to the high-cost of test equipment having so many different test functions. Thus, there is a need for methods and systems of testing a DUT that reduce testing costs.

### SUMMARY OF THE INVENTION

An exemplary embodiment of the present invention includes a pipeline test apparatus. The pipeline apparatus includes a test board. The test board includes a plurality of stages of sockets installed on the test board. Each socket is configured to be connected to a device under test (DUT). The sockets of each stage are connected to one of a plurality of different testing devices. Each testing device is configured to perform a unique test on all the DUTs of a corresponding stage.

The sockets of each stage may be formed as a column on the test board. The columns may be disposed at substantially an equal distance apart from one another. The sockets of each column may be disposed at substantially an equal distance apart from one another. Each testing device may be configured to perform one of an O/S (Open/Short) test, a DFT (Design for Testability) test, a DC (direct current) test, and an analog test.

An exemplary embodiment of the present invention includes a pipeline test apparatus. The pipeline test apparatus includes a test board and a probe card. The probe card is installed on the test board. The probe card is configured to test chips on a wafer according to each of a plurality of test items. The probe card has a plurality of probe tips for contacting electrode pads of the chips.

The probe card may be connected to a test device that is configured to perform each of an O/S test, a DFT test, a DC test, and an analog test on the chips. The probe card may be divided into a plurality of sections, wherein each section further includes a number of subsections corresponding to the number of tests performed by the test device. The test device may be configured to perform each one of the tests on the chips through a different one of the subsections. Each of the subsections may have a rectangular shape. The probe tips may contact the electrode pads by using a vertical probing method.

An exemplary embodiment of the present invention includes a pipeline test method. The method includes installing DUTs in a plurality of sockets on a test board, dividing the plurality of sockets into a plurality of test groups for each of a plurality of test items and testing the DUTs in the plurality of test groups according to each of the corresponding test items, and moving the DUTs in the plurality of test groups to a next plurality of sockets in the plurality of test groups.

The plurality of test groups may be connected to a test device performing each of an O/S test, a DFT test, a DC test, and an analog test on the DUTs. The test device may perform a different one of the tests on each test group.

An exemplary embodiment of the present invention includes a pipeline test method. The method includes testing a plurality of chips on a wafer by using a probe card having probe tips that contact electrode pads of the plurality of chips on the wafer, wherein each of the plurality of chips is tested according to different test items, and testing the plurality of chips by moving the probe card across each chip on the wafer.

The probe card may connected to a test device configured to perform each of an O/S test, a DFT test, a DC test, and an analog test on the plurality of chips. The probe card may be divided into a plurality of sections, wherein each section further includes a number of subsections corresponding to the number of tests performed by the test device. The test device may be configured to perform each one of the tests on the chips through a different one of the subsections. Each of the subsections may have a rectangular shape. The probe tips may contact the electrode pads by a vertical probing method.

### BRIEF DESCRIPTION OF THE DRAWINGS

The present invention will become more apparent by describing in detail exemplary embodiments thereof with reference to the attached drawings in which:

FIG. 1 is a diagram illustrating a conventional method of performing various tests on a test board by using a single socket coupled with a semiconductor device under test (DUT);

FIGS. 2A and 2B are diagrams illustrating a pipeline test method according to an exemplary embodiment of the present invention;

FIG. 3 is a diagram illustrating a multi-parameter test method to which the pipeline test method of FIG. 2B may be applied according to an exemplary embodiment of the present invention;

FIG. 4 is a diagram illustrating a wafer test method to which the pipeline test method of FIG. 2B may be applied according to an exemplary embodiment of the present invention;

FIG. 5 is a diagram illustrating probe cards which are installed on a test board and are used to perform tests, according to an exemplary embodiment of the present invention; and

FIGS. 6A and 6B are diagrams illustrating a wafer test method according to an exemplary embodiment of the present invention.

### DETAILED DESCRIPTION OF EXEMPLARY EMBODIMENTS

Hereinafter, the present invention will be described in detail by explaining exemplary embodiments of the invention with reference to the attached drawings. Like reference numerals in the drawings denote like elements.

FIGS. 2A and 2B are diagrams illustrating a pipeline test method according to an embodiment of the present invention. Referring to FIG. 2A, a plurality of sockets 221, 222, and 223 are installed on a test board 210. Each of the sockets 221, 222, and 223 can perform a different type of test such as an open/short (O/S) test, a design for testability (DFT) test, or an analog test. The sockets 221, 222, and 223 may be arranged in a row or a column on the test board 210. The sockets 221, 22, and 223 may be equally spaced away from one another. When a device under test (DUT) is installed in each of the sockets 221, 222, and 223, only a corresponding test item is performed.

Referring to FIG. 2B, the pipeline test method simultaneously tests a number of different DUTs according to different test items. The number of DUTs may range up to the number of the available sockets 221, 222, and 223. When one test is finished, all of the DUTs are moved together to a next socket. For example, in one embodiment, sockets are in a row and when one of the tests of a corresponding socket finishes, each DUT is together decoupled from its current socket. Then together, each DUT is shifted over one socket and together each DUT is coupled to a next socket. This process may repeat until each test has been executed for each DUT. Each of the tests may take a varying amount of time to complete. In one embodiment, each of the tests take an equal amount of time to complete T1. The DUTs can then be moved at a DUT movement time of T1. However, each of the tests may take a different amount of time to complete. When this occurs, the DUT movement time can be set to the time of the longest test T2. Optimizing the testing times can reduce the DUT movement time.

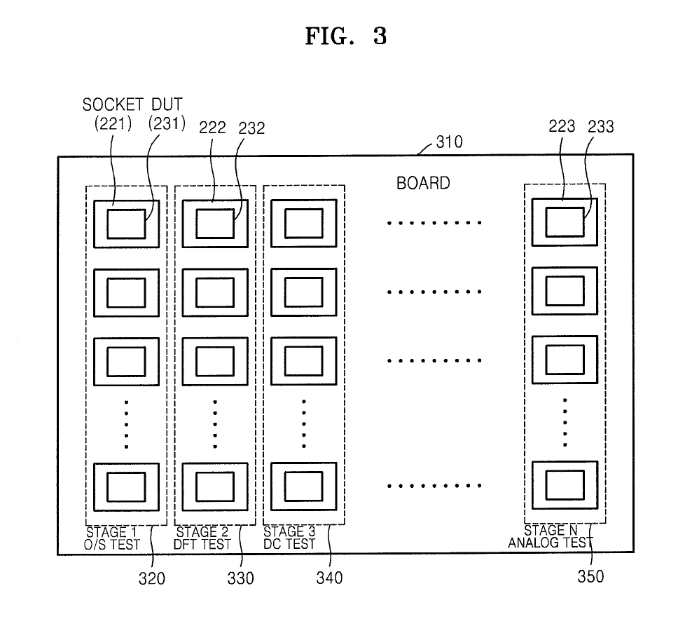

FIG. 3 is a diagram illustrating a multi-parameter test method to which the pipeline test method of FIG. 2B may be applied according to an exemplary embodiment of the present invention. Referring to FIG. 3, a plurality of test stages 320, 330, 340, and 350 are arranged on a test board 310. Each of the test stages 320, 330, 340, and 350 may be connected to low-cost test equipment, which performs tests such as an O/S test, a DFT test, a direct current (DC) test, an analog test, etc. Test equipment that only provides a single test may be considered low-cost test equipment because conventionally test equipment that provides multiple tests has a higher cost due to its complexity.

The sockets 221, 222, and 223 are arranged on each of the plurality of test stages 320, 330, 340, and 350. The DUTs 231, 232, and 233 are coupled with each of the sockets 221, 222, and 223. The multi-parameter test method tests the DUTs 231, 232, and 233 in each of the test stages 320, 330, 340, and 350 according to a corresponding test item of a stage, and then moves the DUTs 231, 232, and 233 to a next stage. For example, in one embodiment, all sockets of a stage are in different columns on the test board 310, and when one of the tests of a socket in a column finishes, each column of DUTs is together decoupled from its current socket. Then together, each column of DUTs is shifted over one stage and together each DUT is coupled to a socket of a next stage. The sockets of each stage may be substantially equally spaced apart on the test board 310. The stages may be substantially equally spaced apart from one another.

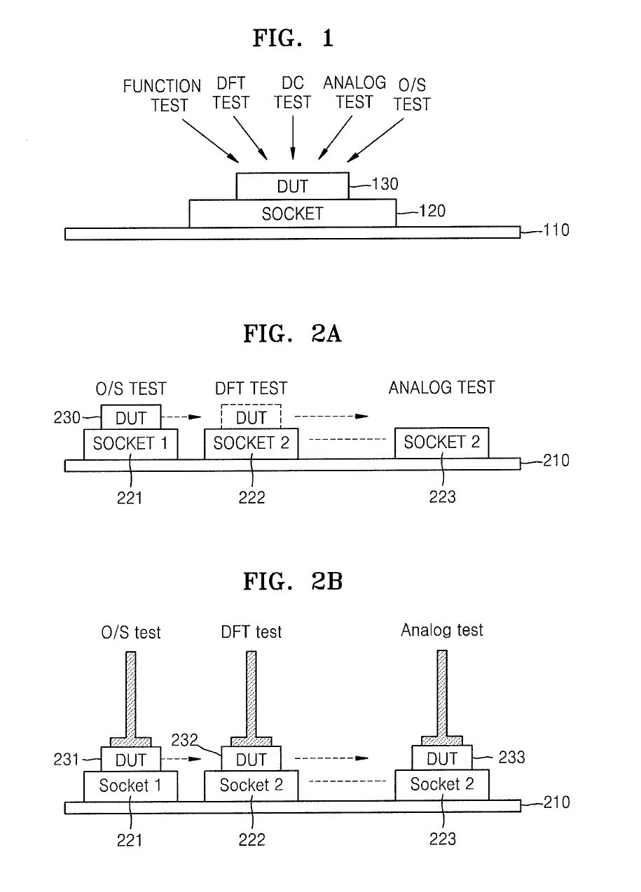

In one embodiment, the tests of each stage take an equal amount of time to complete T3. Each column of DUTs can then be moved at a DUT movement time of T3. However, the tests of each stage may take a different amount of time to complete. When this occurs, the DUT movement time can be set to the time of the longest stage test T4. The multi-parameter test method can improve an overall testing time, thereby reducing testing costs, as compared to a conventional method of performing various tests by using the single socket 120, as illustrated in FIG. 1.

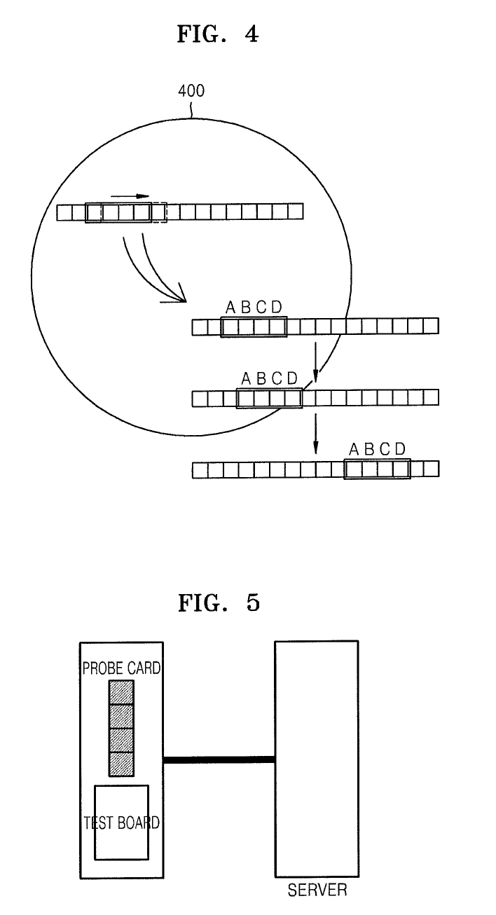

FIG. 4 is a diagram illustrating a wafer test method to which the pipeline test method of FIG. 2B may applied, according to an exemplary embodiment of the present invention. Referring to FIG. 4, chips formed on a wafer 400 are sequentially tested in an order of A, B, C, and D test items. The A, B, C, and D test items may be, for example, a function test, a DFT test, an O/S test, a leakage current test, an analog test, etc. The test items are performed after probe tips of a probe card contact electrode pads in a chip. The probe cards used to perform the A, B, C, and D tests may have the same number of probe tips as the number of electrode pads in the chip. The probe tips may be arranged uniformly. The probe tips may be manufactured to contact the electrode pads by using a vertical probing method. The probe cards used to perform the A, B, C, and D tests may be coupled with a test board as illustrated in FIG. 5. The probe card may be divided into a plurality of sections. Each section may then be further subdivided into a plurality of different subsections corresponding to the number of tests performed by a test device. The test device may be configured to perform one of the tests on the chip through a different one of the subsections. The subsections may have a rectangular shape.

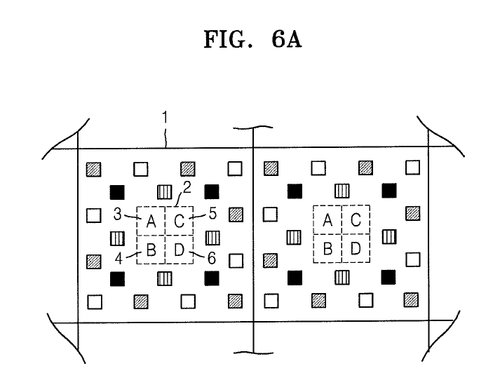

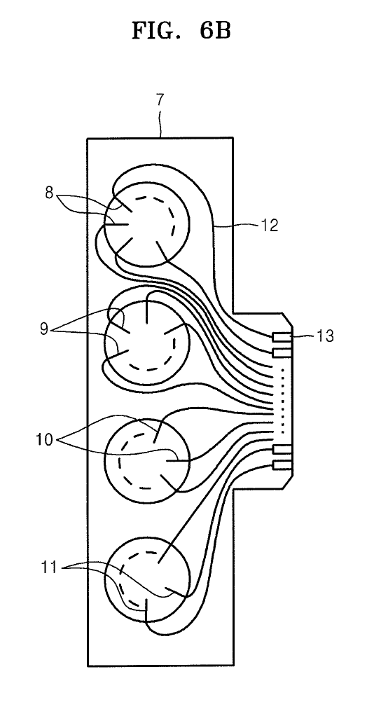

FIGS. 6A and 6B illustrates a wafer test method according to an exemplary embodiment of the present invention, which differs from the wafer test method illustrated in FIG. 4. A plurality of electrodes 3,4,5, and 6 illustrated in FIG. 6A divide an entire circuit block 2 in a semiconductor integrated circuit device (e.g., a chip) 1 into a plurality of circuit blocks A, B, C, and D, and test each of the corresponding circuit blocks A, B, C, and D. FIG. 6B illustrates a probe card 7 including probe tips 8 and 9 for contacting the circuit blocks A and B and probe tips 10 and 11 for contacting the circuit blocks C and D. The circuit blocks A and B of the chip 1, and the circuit blocks C and D of the chip 1 may be separately and simultaneously tested. For example, a test such as the DC test may be performed separately on each the blocks A, B, C, and D. However, the function test, DFT test, O/S test, leakage current test, and analog test are more appropriate for the entire circuit block 2 of the chip 1.

A wafer test method according to at least one embodiment of the present invention tests the entire circuit block 2 of the chip 1 by using a pipeline architecture according to each of a plurality of test items, thereby enabling a testing time for each wafer to be reduced.

While this invention has been particularly shown and described with reference to exemplary embodiments thereof, it will be understood by those of ordinary skill in the art that various changes in form and details may be made therein without departing from the spirit and scope of the invention.

What is claimed is:

1. A pipeline test apparatus, comprising:
a test board comprising a plurality of stages of sockets installed on the test board, wherein each socket is configured to be connected to a device under test (DUT), the sockets of each stage are connected to one of a plurality of different testing devices, and each testing device is configured to perform a unique test on all the DUTs of a corresponding stage.

2. The pipeline test apparatus of claim 1, wherein the sockets of each stage are formed as a column on the test board.

3. The pipeline test apparatus of claim 2, wherein the columns are disposed at substantially an equal distance apart from one another.

4. The pipeline test apparatus of claim 3, wherein the sockets of each column are disposed at substantially an equal distance apart from one another.

5. The pipeline test apparatus of claim 1, wherein each testing device is configured to perform one of an O/S (Open/Short) test, a DFT (Design for Testability) test, a DC (direct current) test, and an analog test.

6. A pipeline test apparatus, comprising
a test board; and
a probe card installed on the test board, wherein the probe card is configured to test chips on a wafer according to each of a plurality of test items, the probe card having a plurality of probe tips for contacting electrode pads of the chips.

7. The pipeline test apparatus of claim 7, wherein the probe card is connected to a test device that is configured to perform each of an O/S test, a DFT test, a DC test, and an analog test on the chips.

8. The pipeline test apparatus of claim 7, wherein the probe card is divided into a plurality of sections, wherein each section further includes a number of subsections corresponding to the number of tests performed by the test device.

9. The pipeline test apparatus of claim 8, wherein the test device is configured to perform each one of the tests on the chips through a different one of the subsections.

10. The pipeline test apparatus of claim 8, wherein each of subsections have a rectangular shape.

11. The pipeline test apparatus of claim 6, wherein the probe tips contact the electrode pads by using a vertical probing method.

12. A pipeline test method, comprising:
installing DUTs in a plurality of sockets on a test board;
dividing the plurality of sockets into a plurality of test groups for each of a plurality of test items and testing the DUTs in the plurality of test groups according to each of the corresponding test items; and
moving the DUTs in the plurality of test groups to a next plurality of sockets in the plurality of test groups.

13. The pipeline test method of claim 12, wherein the plurality of test groups are connected to a test device performing each of an O/S test, a DFT test, a DC test, and an analog test on the DUTs.

14. The pipeline test method of claim 13, wherein the test device performs a different one of the tests on each test group.

15. A pipeline test method, comprising:
testing a plurality of chips on a wafer by using a probe card having probe tips that contact electrode pads of the plurality of chips on the wafer, wherein each of the plurality of chips is tested according to different test items; and
testing the plurality of chips by moving the probe card across each chip on the wafer.

16. The pipeline test method of claim 15, wherein the probe card is connected to a test device configured to perform each of an O/S test, a DFT test, a DC test, and an analog test on the plurality of chips.

17. The pipeline test apparatus of claim 16, wherein the probe card is divided into a plurality of sections, wherein each section further includes a number of subsections corresponding to the number of tests performed by the test device.

18. The pipeline test apparatus of claim 17, wherein the test device is configured to perform each one of the tests on the chips through a different one of the subsections.

19. The pipeline test method of claim 18, wherein each of subsections have a rectangular shape.

20. The pipeline test method of claim 15, wherein the probe tips contact the electrode pads by a vertical probing method.
